(19) United States
(12) Patent Application Publication
(10) Pub. No.: US 2022/0209174 A1
(43) Pub. Date: Jun. 30, 2022

(54) DISPLAY DEVICE AND MANUFACTURING METHOD THEREOF

(71) Applicant: LG DISPLAY CO., LTD., Seoul (KR)

(72) Inventor: Joungwon WOO, Paju-si (KR)

(73) Assignee: LG DISPLAY CO., LTD., SEOUL (KR)

(21) Appl. No.: 17/558,547

(22) Filed: Dec. 21, 2021

(30) Foreign Application Priority Data
Dec. 31, 2020 (KR) 10-2020-0189039

(51) Int. Cl. H01L 51/52; H01L 51/56

(52) U.S. Cl. CPC H01L 51/5228; H01L 51/56; H01L 27/3248; H01L 2251/308; H01L 2227/323

(57) ABSTRACT

A display device includes a substrate on which a light emitting area and an auxiliary electrode contact part are defined; an auxiliary electrode which is formed on the substrate and is connected to a low potential driving power; a conductive layer which is formed on the auxiliary electrode in the auxiliary electrode contact part; an organic layer which covers the conductive layer; and a cathode electrode which is formed on the organic layer, and the conductive layer is formed of a material having a lower surface tension than that of the organic layer.

### CROSS-REFERENCE TO RELATED APPLICATION

The present application claims the priority to Korean Patent Application No. 10-2020-0189039, filed on Dec. 31, 2020, which is hereby incorporated by reference.

### BACKGROUND

### Field of the Disclosure

The present disclosure relates to a display device and a manufacturing method thereof.

### Description of the Background

An organic light emitting device (hereinafter, referred to as a light emitting device) constituting the OLED emits light by itself without a separate light source, and thus, the OLED can be thinner and lighter. Also, the OLED shows desirable characteristics such as low power consumption, high luminance, fast response time, etc.

In general, the light emitting device has a structure in which an anode electrode, a bank surrounding the edge region of the anode electrode, a light emitting layer formed on the anode electrode within the bank, and the cathode electrode covering the light emitting layer and the bank are stacked. Such a light emitting device emits light with a required luminance by controlling the amount of current flowing through the light emitting device by a driving transistor.

### SUMMARY

The present disclosure is to provide a display device without an organic layer formed between an auxiliary electrode and a cathode electrode through a reflow process, and a manufacturing method thereof.

More specifically, the present disclosure is to provide a display device in which direct contact is made between the auxiliary electrode and the cathode electrode while maintaining an adhesive strength between the organic layer and the cathode electrode in an auxiliary electrode contact part.

In an aspect of the present disclosure, a display device includes a substrate on which a light emitting area and an auxiliary electrode contact part are defined; an auxiliary electrode which is formed on the substrate and is connected to a low potential driving power; a conductive layer which is formed on the auxiliary electrode in the auxiliary electrode contact part; an organic layer which covers the conductive layer; and a cathode electrode which is formed on the organic layer. The conductive layer is formed of a material having a lower surface tension than that of the organic layer.

The organic layer includes at least one opening which exposes at least one region of the conductive layer. The cathode electrode is in direct contact with the conductive layer through the at least one opening.

The cathode electrode includes: a first cathode electrode which is formed on a region of the auxiliary electrode, where the at least one opening is not formed; and a second cathode electrode which covers the first cathode electrode and is in direct contact with the conductive layer through the at least one opening.

The first cathode electrode and the second cathode electrode include magnesium. A content of the magnesium of the second cathode electrode is less than a content of the magnesium of the first cathode electrode.

The conductive layer is formed of one of Nafion, PCPDT-2T, and polyaniline (PANT).

An uppermost layer of the auxiliary electrode is composed of indium tin oxide (ITO).

The organic layer is an electron transport layer or an electron injection layer.

The display device further includes a bank layer which is formed on the auxiliary electrode and exposes a region of the auxiliary electrode in the auxiliary electrode contact part.

A portion of a surface of the bank layer has at least hydrophobicity.

A surface of a central region of the conductive layer is lower than a surface of an edge region of the conductive layer.

In another aspect of the present disclosure, a manufacturing method of the display device includes forming, on a substrate on which a light emitting area and an auxiliary electrode contact part are defined, an auxiliary electrode which is formed on the substrate and is connected to a low potential driving power; forming, in the auxiliary electrode contact part, a conductive layer on the auxiliary electrode; forming an organic layer which covers the conductive layer; forming a first cathode electrode on the organic layer; and performing a reflow process by irradiating a laser to the auxiliary electrode contact part. During the reflow process, at least a portion of the organic layer is melted to expose at least one region of the conductive layer.

The conductive layer is formed of a material having a lower surface tension than that of the organic layer.

During the reflow process, at least a portion of the organic layer is melted and flows due to a difference in the surface tension from the conductive layer.

At least one opening which exposes at least one region of the auxiliary electrode is formed in the organic layer and the first cathode electrode by the flowing of the melted organic layer.

The manufacturing method further includes forming a second cathode electrode on the first cathode electrode.

The second cathode electrode is in direct contact with the conductive layer through the at least one opening.

The conductive layer is formed of one of Nafion, PCPDT-2T, and polyaniline (PANT).

The manufacturing method further includes, forming, after the forming the auxiliary electrode, on the auxiliary electrode, a bank layer which exposes a region of the auxiliary electrode in the auxiliary electrode contact part. A portion of a surface of the bank layer has at least hydrophobicity.

The forming the conductive layer includes applying a solution for forming the conductive layer on the exposed region of the auxiliary electrode; and drying the applied solution.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 shows a cross-sectional structure of a display device according to the present disclosure;

FIG. 2 is an enlarged views of area AA of FIG. 1 according to one aspect of the present disclosure;

FIG. 3 is an enlarged views of area AA of FIG. 1 according to another aspect of the present disclosure;

FIG. 4 is an enlarged views of area BB of FIG. 1 according to the one aspect of the present disclosure;

FIG. 5 is an enlarged views of area CC of FIG. 1 according to the one aspect of the present disclosure;

FIGS. 6 to 10 are schematic views illustrating a manufacturing method of the display device according to the present disclosure;

FIGS. 11 to 15 are schematic views illustrating shape changes of an organic layer melted on an auxiliary electrode; and

FIG. 16 is a graph showing current characteristics of an auxiliary electrode connection portion.

### DETAILED DESCRIPTION

Hereinafter, aspects of the present disclosure will be described with reference to the accompanying drawings. In this specification, when it is mentioned that a component (or region, layer, portion) “is on”, “is connected to”, or “is combined with” another component, terms “is on”, “connected to”, or “combined with” mean that a component may be directly connected to/combined with another component or mean that a third component may be disposed between them.

The same reference numerals correspond to the same components. Also, in the drawings, the thicknesses, ratios, and dimensions of the components are exaggerated for effective description of the technical details. A term “and/or” includes all of one or more combinations that related configurations can define.

While terms such as the first, the second, etc., can be used to describe various components, the components are not limited by the terms mentioned above. The terms are used only for distinguishing between one component and other components. For example, the first component may be designated as the second component without departing from the scope of rights of various aspects. Similarly, the second component may be designated as the first component. An expression of a singular form includes the expression of plural form thereof unless otherwise explicitly mentioned in the context.

Terms such as “below”, “lower”, “above”, “upper” and the like are used to describe the relationships between the components shown in the drawings. These terms have relative concepts and are described based on directions indicated in the drawings.

In the present specification, it should be understood that the term “include” or “comprise” and the like is intended to specify characteristics, numbers, steps, operations, components, parts or any combination thereof which are mentioned in the specification, and intended not to previously exclude the possibility of existence or addition of at least one another characteristics, numbers, steps, operations, components, parts or any combination thereof.

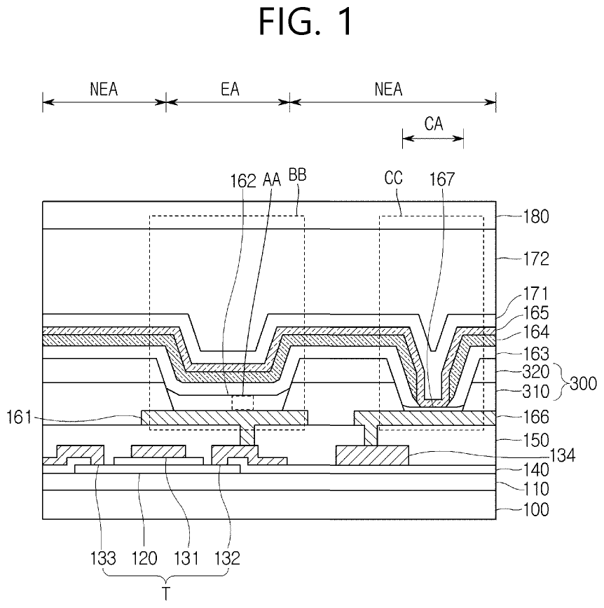

FIG. 1 shows a cross-sectional structure of a display device according to the present disclosure.

A display device according to the present disclosure includes a substrate 100 on which a plurality of pixels are disposed, a circuit element layer which is disposed on the substrate 100 and on which a plurality of circuit elements for driving the plurality of pixels are disposed, and a light emitting device layer which is disposed on the circuit element layer and on which light emitting devices of the plurality of pixels are disposed.

Referring to FIG. 1, the substrate 100 is a base material and may be a light-transmitting substrate. The substrate 100 may be a rigid substrate including glass or tempered glass or a flexible substrate made of plastic. The substrate 100 may include a light emitting area EA and a non-light emitting area NEA. The non-light emitting area NEA may include an auxiliary electrode contact part CA.

A buffer layer 110 is formed on the substrate 100. The buffer layer 110 can prevent diffusion of ions or impurities from the substrate 100 and block moisture penetration. The buffer layer 110 may be formed through one of a chemical vapor deposition process, a spin coating process, a plasma enhanced chemical vapor deposition process, a sputtering process, a vacuum deposition process, a high-density plasma chemical vapor deposition process, a printing process, or the like.

An active layer 120 is formed on the buffer layer 110. The active layer 120 may be formed of a silicon-based semiconductor material or an oxide-based semiconductor material. The active layer 120 may include a source region and a drain region which include p-type or n-type impurities, and a channel formed between the source region and the drain region.

A conductive layer is formed on the active layer 120. The conductive layer may include a gate electrode 131 disposed to overlap with the channel region of the active layer 120, and a source electrode 132 and a drain electrode 133 which are connected to the source and drain regions of the active layer 120, respectively. The gate electrode 131, the source electrode 132, the drain electrode 133, and the active layer 120 corresponding thereto may constitute a transistor T.

The conductive layer may further include a bridge electrode 134. The bridge electrode 134 may be connected to power wiring for applying a low potential driving power to the pixel.

The conductive layer may be formed of one of molybdenum (Mo), aluminum (Al), chromium (Cr), gold (Au), titanium (Ti), nickel (Ni), neodymium (Nd) and copper (Cu), or may be formed of an alloy thereof. The conductive layer may be formed as a single layer or multiple layers.

An insulating layer 140 may be interposed between the active layer 120 and the conductive layer. The insulating layer 140 may be a silicon oxide (SiOx) layer, a silicon nitride (SiNx) layer, or multilayers thereof.

An overcoat layer 150 may be formed on the conductive layer. The overcoat layer 150 may be a planarization layer for reducing a step difference in the structure thereunder. According to the present disclosure, an insulating layer (e.g., a protective layer) for protecting the devices thereunder may be further formed between the conductive layer and the overcoat layer 150.

The light emitting device layer is formed on the overcoat layer 150. Specifically, an anode electrode 161 of the light emitting device is formed on the overcoat layer 150. The anode electrode 161 may be patterned to correspond to the light emitting area EA. The anode electrode 161 may be connected to the transistor T through a via-hole which passes through the overcoat layer 150.

An auxiliary electrode 166 is further formed on the overcoat layer 150. The auxiliary electrode 166 may be disposed in the auxiliary electrode contact part CA of the non-light emitting area NEA, may be made of the same material as the anode electrode 161, and may be formed by the same process as the anode electrode 161. The auxiliary electrode 166 may be connected to the bridge electrode 134 through the via-hole which passes through the overcoat layer 150.

A bank 300 is further formed on the overcoat layer 150. The bank 300 is formed to expose some regions of the anode electrode 161, for example, a central region and to cover the remaining region, for example, edges of the anode electrode 161.

In the present disclosure, the bank 300 may have a structure in which a hydrophilic bank 310 and a hydrophobic bank 320 are stacked.

The hydrophilic bank 310 may be formed to expose the central region of the anode electrode 161 and to cover the edges. The exposed region of the anode electrode 161, which is not covered by the hydrophilic bank 310, may be defined as the light emitting area EA. The hydrophilic bank 310 is made of a hydrophilic inorganic insulating material such as silicon oxide (SiO₂) or silicon nitride (SiNx), so that a solution spreads well in the formation of a light emitting layer 162, which will be described later.

The hydrophobic bank 320 may be formed in a partial region on the hydrophilic bank 310. The hydrophobic bank 320 may be disposed between pixel rows to partition the pixel rows. The hydrophobic bank 320 is formed such that at least one region, for example, an upper region, has hydrophobicity, thereby preventing color mixing between the pixel rows.

In the non-light emitting area NEA, the bank 300 may be formed to expose a region of the auxiliary electrode 166. The exposed region of the auxiliary electrode 166, which is not covered by the bank 300, may be defined as the auxiliary electrode contact part CA of the pixel.

The light emitting layer 162 is formed on the exposed region of the anode electrode 161 surrounded by the bank 300. The light emitting layer 162 may be formed by a solution process as shown. For example, a solution for forming the light emitting layer 162 within the light emitting area EA may be applied. The solution may be manufactured by mixing organic materials constituting the light emitting layer 162 with a solvent. The solution may be jetted to the light emitting area through an inkjet apparatus having a nozzle mounted on an inkjet head. The applied ink is dried to form the light emitting layer 162. In the light emitting layer 162 formed through the solution process, the surface of the central region may be lower than the surface of the edge region.

In the present disclosure, organic layers such as a hole injection layer (HIL) and a hole transport layer (HTL) may be further formed between the anode electrode 161 and the light emitting layer 162.

A conductive layer 167 is further formed on the exposed region of the auxiliary electrode 166 surrounded by the bank 300. The conductive layer 167 may be formed by the solution process as shown. For example, a solution for forming the conductive layer 167 in the auxiliary electrode contact part CA may be jetted, and the solution may be dried to form the conductive layer 167. Here, the solution may be dried, for example, at about 230° C. for about 10 minutes. In the conductive layer 167 to be formed by the solution process, the surface of the central region may be lower than the surface of the edge region. However, the aspect is not limited thereto.

The conductive layer 167 is formed to have a relatively low surface tension. To this end, the conductive layer 167 may be formed of a material having a low surface energy. For example, the conductive layer 167 may be made of one of Nafion, PCPDT-2T, polyaniline (PANT), etc.

The solution process for forming the light emitting layer 162 and the solution process for forming the conductive layer 167 may be performed in one process or in separate processes. For example, after a solution for forming the conductive layer 167 is applied to the auxiliary electrode contact part CA and the conductive layer 167 is formed by drying the substrate 100, the light emitting layer 162 can be formed in the light emitting area EA. In the conductive layer 167 formed by the solution process, the surface of the central region may be lower than the surface of the edge region. However, the present disclosure t is not limited thereto.

An organic layer 163 is formed on the light emitting layer 162 and the conductive layer 167. The organic layer 163 may be widely formed on the light emitting area EA and the non-light emitting area NEA. The organic layer 163 may be, for example, an electron transport layer (ETL) or an electron injection layer (EIL). The organic layer 163 serves to smoothly transfers electrons injected from a below-described second cathode electrode 165 to the light emitting layer 162.

In order to efficiently melt the organic layer 163 in a reflow process to be described later, the organic layer 163 may be formed to have a thin layer. Here, in order not to deteriorate optical characteristics of the light emitting device, the organic layer 163 may be formed to have a thickness of about 50 nm or less.

The organic layer 163 may be formed to expose the central region of the conductive layer 167 and cover the edges of the conductive layer 167.

A first cathode electrode 164 is formed on the organic layer 163. The first cathode electrode 164 may be widely formed on the light emitting area EA and the non-light emitting area NEA. Here, the first cathode electrode 164 may be formed to expose the central region of the conductive layer 167 and cover the edges of the conductive layer 167.

The first cathode electrode 164 may be formed of a transparent conductive material (TCO) or a semi-transmissive conductive material which is capable of transmitting light. For example, silver (Ag) and magnesium (Mg) are co-deposited and then deposited on the organic layer 163, so that the first cathode electrode 164 can be formed. The deposition of the first cathode electrode 164 may be performed by an evaporation deposition method such as thermal deposition or by a physical vapor deposition method such as a sputtering method. In the aspect, the first cathode electrode 164 may be formed to have a thickness of 1 nm to 10 nm, and is not limited thereto.

The second cathode electrode 165 is formed on the first cathode electrode 164. The second cathode electrode 165 may be formed of the same material as the first cathode electrode 164. For example, the second cathode electrode 165 may be formed of a transparent conductive material such as ITO and IZO, etc., or a semi-transmissive conductive material such as silver and magnesium. In the aspect, when the second cathode electrode 165 is made of silver and magnesium, the ratio of magnesium may be less than that of the first cathode electrode 164.

A region of the conductive layer 167, which is exposed to the outside without being covered by the organic layer 163 and the first cathode electrode 164, may be covered by the second cathode electrode 165. That is, the exposed region of the conductive layer 167 is in direct contact with the second cathode electrode 165. Here, since the auxiliary electrode 166 and the second cathode electrode 165 are electrically directly connected to each other through the conductive layer 167, resistance between the auxiliary electrode 166 and the second cathode electrode 165 can be minimized.

An encapsulation layer 171 may be formed on the second cathode electrode 165. The encapsulation layer 171 serves to prevent external moisture from penetrating into the light emitting layer 162. The encapsulation layer 171 may be formed of an inorganic insulating material or may have a structure in which an inorganic insulating material and an organic insulating material are alternately stacked, and is not limited thereto.

A cover substrate 180 may be formed on the encapsulation layer 171. The cover substrate 180 may be made of the same material as the substrate 100. The cover substrate 180 may be adhered to the encapsulation layer 171 through an adhesive 172, etc.

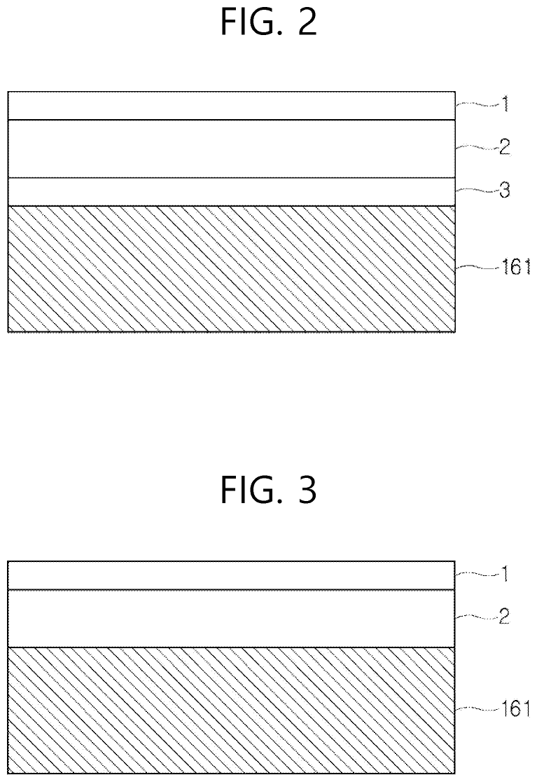

FIG. 2 is an enlarged views of area AA of FIG. 1 according to one aspect of the present disclosure. FIG. 3 is an enlarged views of area AA of FIG. 1 according to another aspect of the present disclosure.

The anode electrode 161 may be formed of a transparent conductive material such as indium tin oxide (ITO), indium zinc oxide (IZO) and zinc oxide (ZnO), etc. The anode electrode 161 may be formed as a triple layer or a double layer.

In the one aspect, the anode electrode 161 may be, as shown in FIG. 2, formed as a triple layer composed of a transparent conductive layer 1/a reflective layer (a metal oxide layer) 2/a transparent conductive layer 3. Here, the transparent conductive layer may be formed of ITO or IZO and may have a thickness of 10 nm to 150 nm. The reflective layer may be formed of silver (Ag) and may have a thickness of 50 nm to 200 nm.

In another aspect, the anode electrode 210 may be, as shown in FIG. 3, formed as a double layer composed of the transparent conductive layer (1)/the reflective layer (2).

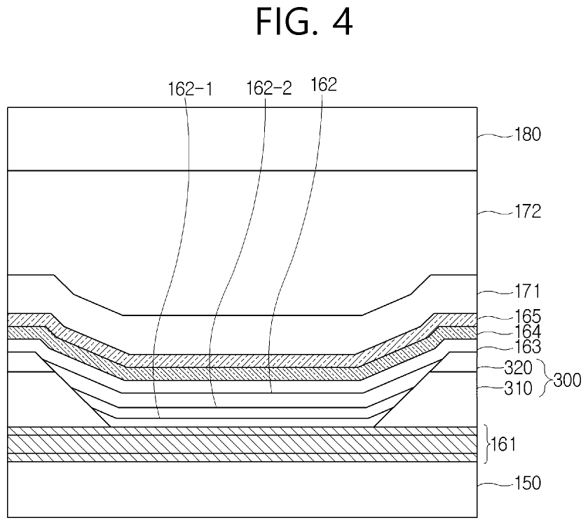

FIG. 4 is an enlarged views of area BB of FIG. 1 according to the aspect. Specifically, FIG. 4 is an enlarged cross-sectional view showing the light emitting area EA of FIG. 1.

Referring to FIG. 4, the anode electrode 161 is formed on the overcoat layer 150 in the light emitting area EA. The anode electrode 161 may have, for example, a triple layer structure in which ITO/Ag/ITO are stacked. The bank 300 is formed at the edge of the anode electrode 161 and defines the light emitting area EA. A hole injection layer 162-1, a hole transport layer 162-2, and the light emitting layer 162 may be sequentially stacked on the anode electrode 161 in the light emitting area EA.

The organic layer 163 and the first cathode electrode 164 are widely formed on the light emitting area EA. The organic layer 163 may be an electron transport layer or an electron injection layer.

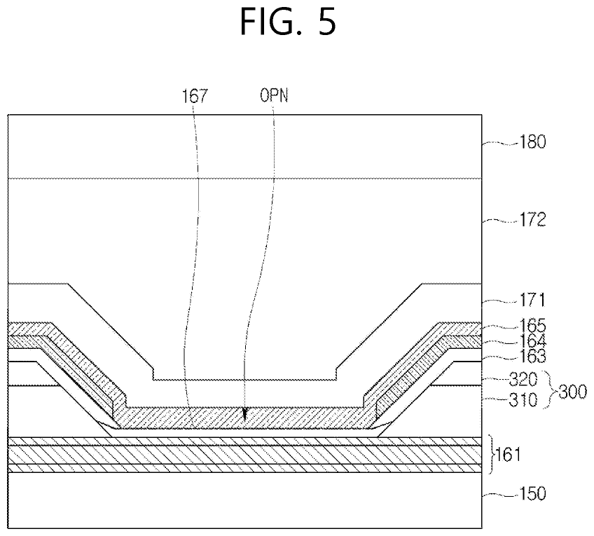

FIG. 5 is an enlarged views of area CC of FIG. 1 according to the aspect. Specifically, FIG. 5 is an enlarged cross-sectional view showing the auxiliary electrode contact part CA of FIG. 1.

Referring to FIG. 5, the auxiliary electrode 166 is formed on the overcoat layer 150 in the auxiliary electrode contact part CA. The auxiliary electrode 166 may have a triple layer structure in which ITO/Ag/ITO are stacked in the same manner as the anode electrode 161. The bank 300 is formed at the edge of the auxiliary electrode 166 and defines the auxiliary electrode contact part CA. The conductive layer 167 is formed on the auxiliary electrode 166 in the auxiliary electrode contact part CA.

An opening OPN which exposes a region of the conductive layer 167 may be formed in the organic layer 163 and the first cathode electrode 164. The second cathode electrode 165 is widely formed on the light emitting area EA and the auxiliary electrode contact part CA. The second cathode electrode 165 can directly contact the exposed region of the conductive layer 167 through the opening formed in the organic layer 163 and the first cathode electrode 164. Also, the second cathode electrode 165 may be electrically connected to the auxiliary electrode 166 via the conductive layer 167.

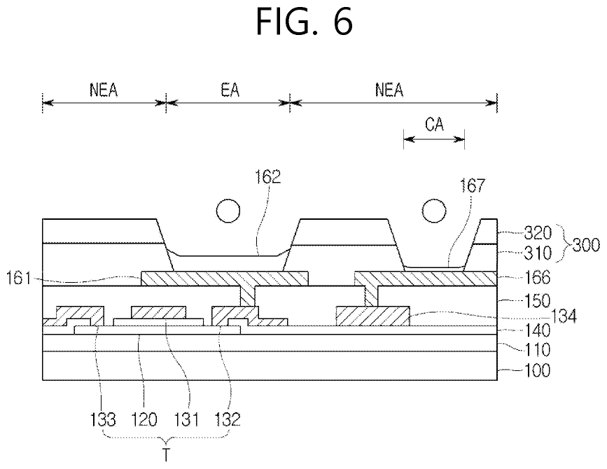

FIGS. 6 to 10 are schematic views illustrating a manufacturing method of the display device according to the present disclosure.

Referring to FIG. 6, the buffer layer 110 is formed on the substrate 100. The buffer layer 110 may be formed by a chemical vapor deposition process, a spin coating process, a plasma enhanced chemical vapor deposition process, a sputtering process, a vacuum deposition process, a high-density plasma-chemical vapor deposition process, a printing process, or the like.

The active layer 120 is formed on the buffer layer 110. The active layer 120 may be formed of a silicon-based semiconductor material or an oxide-based semiconductor material. The active layer 120 may include a source region and a drain region which include p-type or n-type impurities, and a channel formed between the source region and the drain region.

The conductive layer is formed on the active layer 120. The conductive layer may include the gate electrode 131 disposed to overlap with the channel region of the active layer 120, and the source electrode 132 and the drain electrode 133 which are connected to the source and drain regions of the active layer 120, respectively. The gate electrode 131, the source electrode 132, the drain electrode 133, and the active layer 120 corresponding thereto may constitute a transistor T. The conductive layer may further include the bridge electrode 134. The bridge electrode 134 may be connected to power wiring for applying a low potential driving power to the pixel.

The conductive layer may be formed of one of molybdenum (Mo), aluminum (Al), chromium (Cr), gold (Au), titanium (Ti), nickel (Ni), neodymium (Nd) and copper (Cu), or may be formed of an alloy thereof. The conductive layer may be formed as a single layer or multiple layers.

The insulating layer 140 may be interposed between the active layer 120 and the conductive layer. The insulating layer 140 may be a silicon oxide (SiOx), a silicon nitride (SiNx), or a multilayer thereof.

The overcoat layer 150 may be formed on the conductive layer. The overcoat layer 150 may be a planarization layer for reducing a step difference in the structure thereunder.

The light emitting device layer is formed on the overcoat layer 150. Specifically, the anode electrode 161 of the light emitting device is formed on the overcoat layer 150. The anode electrode 161 may be patterned to correspond to the light emitting area EA. The anode electrode 161 may be connected to the transistor T through a via-hole which passes through the overcoat layer 150.

The auxiliary electrode 166 is further formed on the overcoat layer 150. The auxiliary electrode 166 may be disposed in the auxiliary electrode contact part CA of the non-light emitting area NEA, may be made of the same material as the anode electrode 161, and may be formed by the same process as the anode electrode 161. The auxiliary electrode 166 may be connected to the bridge electrode 134 through the via-hole which passes through the overcoat layer 150.

The bank 300 is further formed on the overcoat layer 150. The bank 300 is formed to expose some regions of the anode electrode 161, for example, a central region and to cover the remaining region, for example, edges of the anode electrode 161. The exposed region of the anode electrode 161, which is not covered by the bank 300, may be defined as the light emitting area EA of the pixel.

In the non-light emitting area NEA, the bank 300 may be formed to expose a region of the auxiliary electrode 166. The exposed region of the auxiliary electrode 166, which is not covered by the bank 300, may be defined as the auxiliary electrode contact part CA of the pixel.

At least a portion of the surface of the bank 300 may be formed to have hydrophobicity. For example, the bank 300 may be formed by applying a solution in which a hydrophobic material such as fluorine (F) is mixed with an organic insulating material and then by a photolithography process. The hydrophobic material such as fluorine can move to the top of the bank 300 by light irradiated during the photolithography process.

The light emitting layer 162 is formed on the exposed region of the anode electrode 161 surrounded by the bank 300. The light emitting layer 162 may be formed by a solution process as shown. For example, a solution for forming the light emitting layer 162 within the light emitting area EA may be applied. The solution may be manufactured by mixing organic materials constituting the light emitting layer 162 with a solvent. The solution may be jetted to the light emitting area through an inkjet apparatus having a nozzle mounted on an inkjet head. The applied ink is dried to form the light emitting layer 162. In the light emitting layer 162 formed through the solution process, the surface of the central region may be lower than the surface of the edge region.

In the aspect, organic layers such as a hole injection layer (HIL) and a hole transport layer (HTL) may be further formed between the anode electrode 161 and the light emitting layer 162.

The conductive layer 167 is further formed on the exposed region of the auxiliary electrode 166 surrounded by the bank 300. The conductive layer 167 may be formed by the solution process as shown. For example, a solution for forming the conductive layer 167 in the auxiliary electrode contact part CA may be jetted, and the solution may be dried to form the conductive layer 167. Here, the solution may be dried, for example, at about 230° C. for about 10 minutes. In the conductive layer 167 to be formed by the solution process, the surface of the central region may be lower than the surface of the edge region. However, the aspect is not limited thereto.

The conductive layer 167 is formed to have a relatively low surface tension. To this end, the conductive layer 167 may be formed of a material having a low surface energy. For example, the conductive layer 167 may be made of Nafion, PCPDT-2T, polyaniline (PANT), etc.

The solution process for forming the light emitting layer 162 and the solution process for forming the conductive layer 167 may be performed in one process or in separate processes. For example, after a solution for forming the conductive layer 167 is applied to the auxiliary electrode contact part CA and the conductive layer 167 is formed by drying the substrate 100, the light emitting layer 162 can be formed in the light emitting area EA. In the conductive layer 167 formed by the solution process, the surface of the central region may be lower than the surface of the edge region. However, the present aspect is not limited thereto.

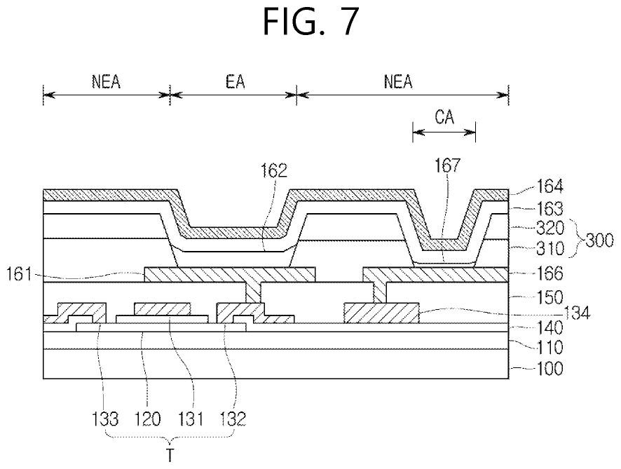

Referring to FIG. 7, the organic layer 163 is formed on the light emitting layer 162 and the conductive layer 167. The organic layer 163 may be widely formed on the light emitting area EA and the non-light emitting area NEA. The organic layer 163 may be, for example, an electron transport layer (ETL) or an electron injection layer (EIL). The organic layer 163 serves to smoothly transfers electrons injected from the below-described second cathode electrode 165 to the light emitting layer 162.

In order to efficiently melt the organic layer 163 in the reflow process to be described later, the organic layer 163 may be formed thin. Here, in order not to deteriorate optical characteristics of the light emitting device, the organic layer 163 may be formed to have a thickness of about 50 nm or less.

The organic layer 163 may be formed to expose the central region of the conductive layer 167 and cover the edges of the conductive layer 167.

The first cathode electrode 164 is formed on the organic layer 163. The first cathode electrode 164 may be widely formed on the light emitting area EA and the non-light emitting area NEA. Here, the first cathode electrode 164 may be formed to expose the central region of the conductive layer 167 and cover the edges of the conductive layer 167.

The first cathode electrode 164 may be formed of a transparent conductive material (TCO) or a semi-transmissive conductive material which is capable of transmitting light. For example, silver (Ag) and magnesium (Mg) are codeposited and then deposited on the organic layer 163, so that the first cathode electrode 164 can be formed. The deposition of the first cathode electrode 164 may be performed by an evaporation deposition method such as thermal deposition or by a physical vapor deposition method such as a sputtering method. In the aspect, the first cathode electrode 164 may be formed to have a thickness of 1 nm to 10 nm, and is not limited thereto.

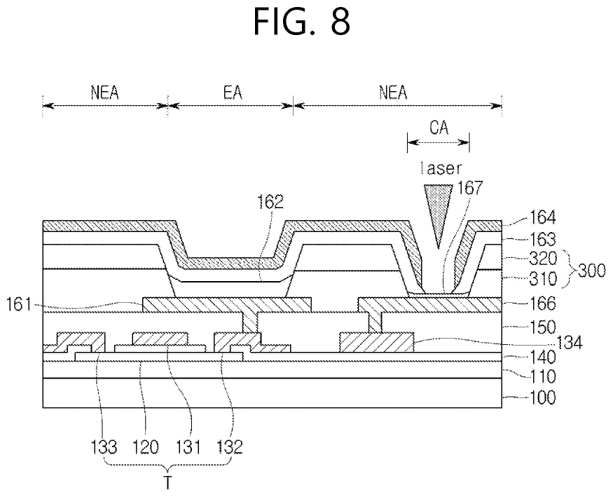

Referring to FIG. 8, the reflow process for the auxiliary electrode contact part CA is performed. To this end, a laser is irradiated to the auxiliary electrode contact part CA. The wavelength of the laser may be 700 nm or more which can be easily absorbed by the auxiliary electrode 166. In the aspect, a diode laser may be used. Although an example in which a laser is irradiated from the below the substrate 100 is shown in the drawing, the laser can be irradiated from above the substrate 100.

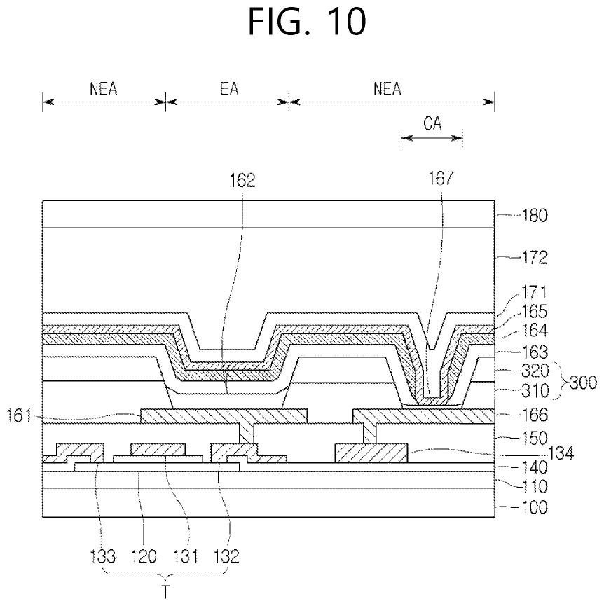

The energy of the laser absorbed by the auxiliary electrode 166 may be transferred to the organic layer 163 and the first cathode electrode 164. The organic layer 163 and the first cathode electrode 164 are melted by the transferred energy. The melted organic layer 163 and the melted first cathode electrode 164 flow in a specific direction in accordance with a difference in the surface tension from the conductive layer 167. Specifically, since the conductive layer 167 has a relatively low surface tension, the melted organic layer 163 and the melted first cathode electrode 164 flow in a direction in which they aggregate. A principle in which the organic layer 163 and the first cathode electrode 164 flow will be described in more detail below with reference to FIGS. 10 to 14.

As the organic layer 163 and the first cathode electrode 164 are induced in a direction in which they aggregate, the organic layer 163 and the first cathode electrode 164 are removed from a region of the conductive layer 167, and an upper portion of the region of the conductive layer 167 may be exposed.

When the entire substrate 100 is heated to a high temperature equal to or higher than a glass transition temperature Tg in order to reflow the organic layer 163 and the first cathode electrode 164, the performance of the light emitting device may be degraded. In the present aspect, by selectively heating only the auxiliary electrode contact part CA by using laser, it is possible to prevent degradation of the performance of the light emitting device.

Also, since the organic layer 163 and the first cathode electrode 164 are removed from a region of the conductive layer 167 through the reflow process using laser, it is possible to prevent a problem that foreign substances and scattering occur when the organic layer 163 and the first cathode electrode 164 are removed by using sublimation.

In the present aspect, the first cathode electrode 164 is formed to cover the organic layer 163 before the reflow process of the organic layer 163. Then, the surface of the organic layer 163 may be covered with the first cathode electrode 164, thereby being protected from contamination generated during the laser process. Also, it is possible to prevent a problem that an adhesive strength between the organic layer 163 and the first cathode 164 is reduce during the high temperature process and thus the characteristics of the light emitting device is deteriorated.

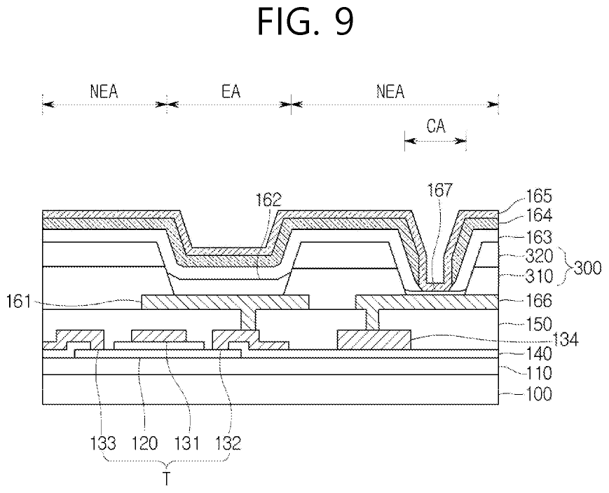

Referring to FIG. 9, the second cathode electrode 165 is formed on the first cathode electrode 164. The second cathode electrode 165 may be formed of the same material as the first cathode electrode 164. For example, the second cathode electrode 165 may be formed of a transparent conductive material such as ITO, IZO, etc., or a semi-transmissive conductive material such as silver and magnesium. In the aspect, when the second cathode electrode 165 is made of silver and magnesium, the ratio of magnesium may be less than that of the first cathode electrode 164.

A region of the conductive layer 167, which is exposed to the outside without being covered by the organic layer 163 and the first cathode electrode 164 by the reflow process, may be covered by the second cathode electrode 165. That is, the exposed region of the conductive layer 167 is in direct contact with the second cathode electrode 165. Here, since the auxiliary electrode 166 and the second cathode electrode 165 are electrically directly connected to each other through the conductive layer 167, resistance between the auxiliary electrode 166 and the second cathode electrode 165 can be minimized.

Referring to FIG. 10, the encapsulation layer 171 may be formed on the second cathode electrode 165. The encapsulation layer 171 serves to prevent external moisture from penetrating into the light emitting layer 162. The encapsulation layer 171 may be formed of an inorganic insulating material or may have a structure in which an inorganic insulating material and an organic insulating material are alternately stacked, and is not limited thereto.

The cover substrate 180 may be formed on the encapsulation layer 171. The cover substrate 180 may be made of the same material as the substrate 100. The cover substrate 180 may be adhered to the encapsulation layer 171 through an adhesive 172, etc.

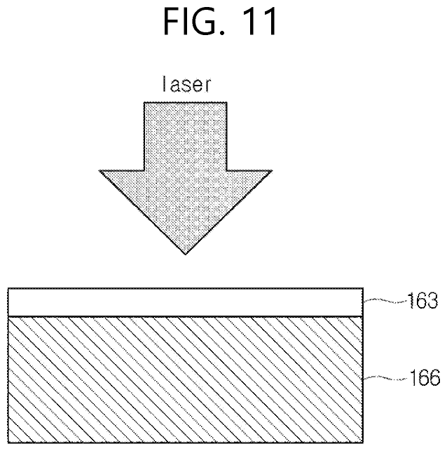

FIGS. 11 to 15 are views for describing shape changes of the organic layer melted on the auxiliary electrode.

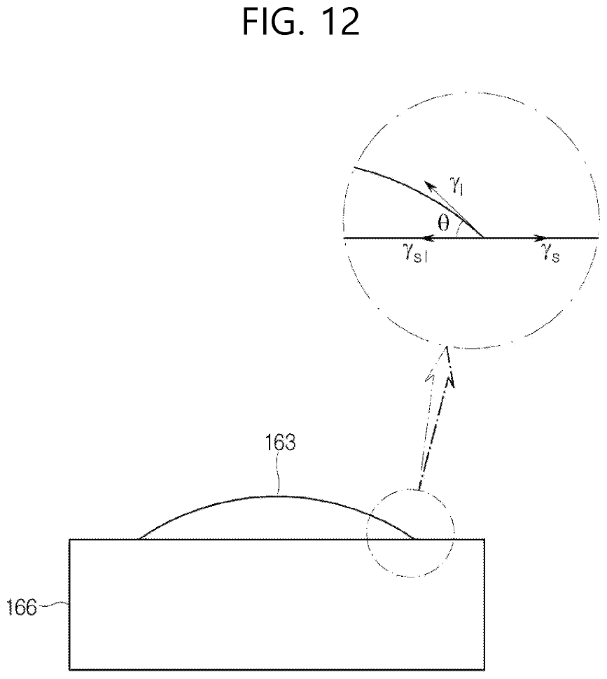

In a general method of manufacturing a display device without the conductive layer 167, the organic layer 163 is widely formed on the light emitting area EA and the non-light emitting area NEA. Here, the organic layer 163 may be formed in the form of a solid film. As shown in FIG. 11, when the organic layer 163 is heated to a temperature equal to or higher than the glass transition temperature Tg by laser irradiation or the like, a portion of the organic layer 163 in the form of a solid film may be, as shown in FIG. 12, converted (melted) into a flowable liquid. The melted organic layer 163 has a difference in surface tension from the auxiliary electrode 166 stacked under the organic layer 163, and has a property of being stabilized in the form of a droplet.

Referring to FIG. 12, at the droplet boundary (contact line) of the melted organic layer 163, an angle (contact angle) 0 between the droplet and the auxiliary electrode 166 may be determined according to the following Equation 1, on the basis of a property that a surface tension intends to achieve a balance between the materials constituting both the organic layer 163 and the auxiliary electrode 166.

γₛ=γₗ×cos θ+γₛₗ Equation (1)

Here, γs is the surface tension of the auxiliary electrode 166, γl is the surface tension of the melted organic layer 163, and γsl is the surface tension at the contact interface between the auxiliary electrode 166 and the melted organic layer 163.

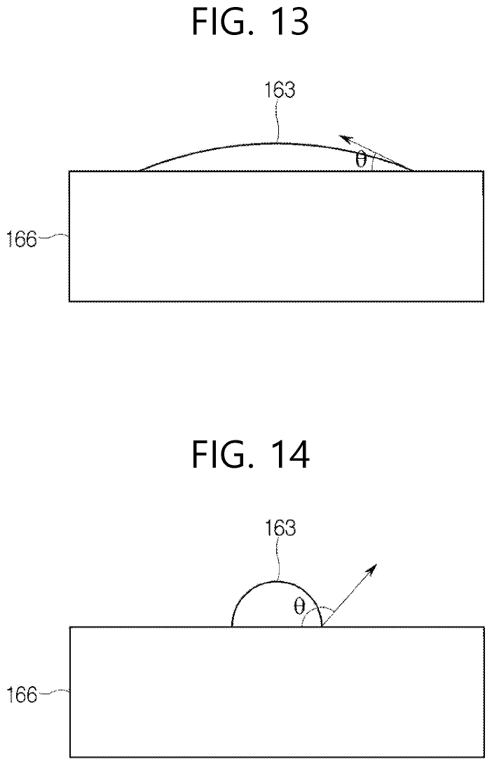

According to Equation 1, when the surface tension of the auxiliary electrode 166 is greater than the surface tension of the melted organic layer 163, the droplet spreads on the auxiliary electrode 166 as shown in FIG. 13. On the contrary, when the surface tension of the auxiliary electrode 166 is smaller than the surface tension of the melted organic layer 163, the droplets aggregate as shown in FIG. 14.

In general, ITO constituting the uppermost layer of the anode electrode 161 and the auxiliary electrode 166 has a relatively large surface tension. Therefore, even if the organic layer 163 is melted on the ITO, the droplet only maintains spreading and does not flow. Accordingly, even though the reflow process is performed, an upper portion of the auxiliary electrode 166 may not be exposed.

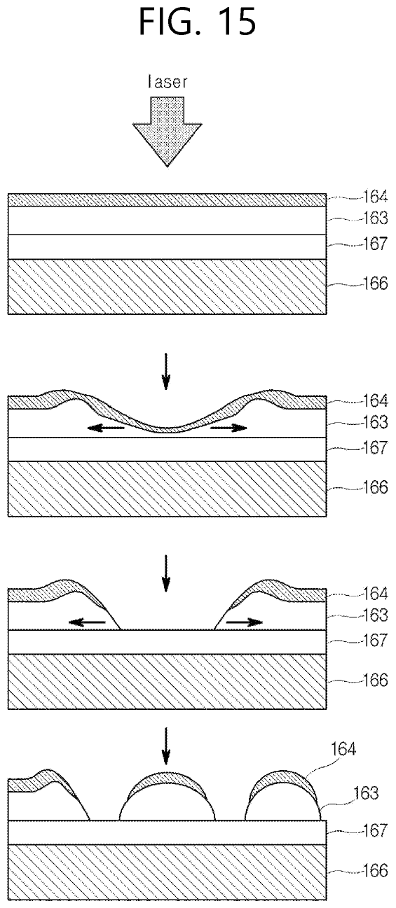

In this aspect, in order to actively induce reflow of the organic layer 163 and the first cathode electrode 164 through the laser process, the conductive layer 167 having a low surface tension is, as shown in FIG. 15, on the auxiliary electrode 166. When the organic layer 163 is formed on the conductive layer 167 having a lower surface tension than that of the organic layer 163, the organic layer 163 may have a non-uniform thickness. When laser is irradiated, the organic layer 163 is first melted in a thin region.

As described with reference to Equation 1, the melted region of the organic layer 163 may flow in such a way that the contact angle θ increases in order to achieve a balance of the surface tension with the conductive layer 167 under the organic layer. That is, the melted region may flow in a direction of aggregating the surrounding region. After the laser process, the dried organic layer 163 is divided into two or more portions as shown in FIG. 15 and exposes an upper portion of the conductive layer 167 under the organic layer.

The first cathode electrode 164 stacked on the organic layer 163 may be separated along the flow of the organic layer 163 and may expose, together with the organic layer 163, an upper portion of the conductive layer 167.

As described above, for the reflow of the organic layer 163, the conductive layer 167 may be formed of a material having a lower surface tension than that of the organic layer 163. For example, the conductive layer 167 may be made of Nafion, PCPDT-2T, polyaniline (PANI), etc.

A contact angle θ when the organic layer 163 is melted on the ITO of the auxiliary electrode 166, and contact angles θ when the organic layer 163 is melted on the conductive layers 167 formed of Nafion, PCPDT-2T, and Polyaniline (PANI), respectively are compared as shown in Table 1 below.

TABLE 1

| Material | Contact angle θ |
|---|---|
| ITO (reference) | 0~30° |
| PCPDT-2T | 0~74° |
| PANI (Polyaniline) | 60~90° |
| NAFION | 85~110° |

Nafion may be represented by the following Formula 1.

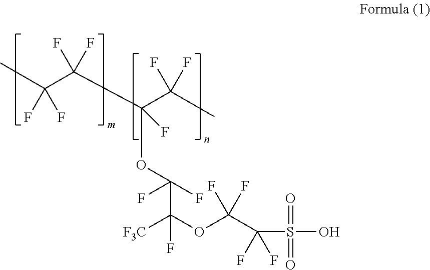

PCPDT-2T may be represented by the following Formula 2.

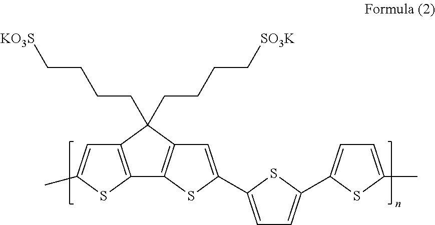

Polyaniline (PANT) may be represented by the following Formula 3.

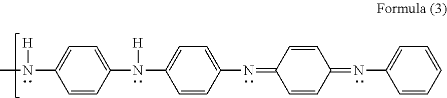 [SMILES: CNc1ccc(Nc2ccc(N=C3C=CC(=Nc4ccccc4)C=C3)cc2)cc1]

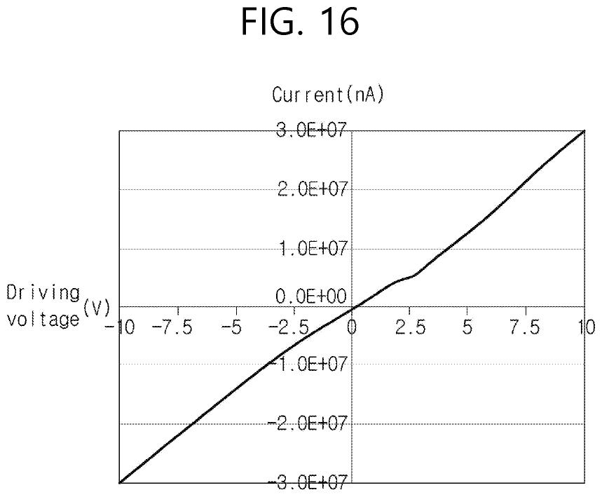

FIG. 16 is a graph showing current characteristics of an auxiliary electrode connection portion.

Referring to FIG. 16, the display device according to the aspect includes the conductive layer 167 formed on the auxiliary electrode 166. Also, the organic layer 163 and the first cathode electrode 164 have an opening which exposes a region of the conductive layer 167. The conductive layer 167 and the second cathode electrode 165 are in direct contact with each other through the opening. The auxiliary electrode 166 and the second cathode electrode 165 may be electrically directly connected to each other through the conductive layer 167.

As described above, as the auxiliary electrode 166 and the second cathode electrode 165 are directly connected, resistance between the auxiliary electrode 166 and the second cathode electrode 165 is reduced. Accordingly, current characteristics between the auxiliary electrode 166 and the second cathode electrode 165 shows ohmic contact characteristics shown in FIG. 16, and the amount of current is improved by more than 5,000 times.

The display device and the manufacturing method thereof according to the aspect reduce resistance between the cathode electrode and the auxiliary electrode, so that power applied through an auxiliary wiring is stably supplied to the cathode electrode.

Accordingly, the display device and the manufacturing method thereof according to the aspect is able to operating characteristics of the display device and to reduce power consumption.

It can be understood by those skilled in the art that the aspects can be embodied in other specific forms without departing from its spirit or essential characteristics. Therefore, the foregoing aspects and advantages are merely exemplary and are not to be construed as limiting the present disclosure. It can be understood by those skilled in the art that the aspects can be embodied in other specific forms without departing from its spirit or essential characteristics. Therefore, the foregoing aspects and advantages are merely exemplary and are not to be construed as limiting the present disclosure. The scopes of the aspects are described by the scopes of the following claims rather than by the foregoing description. All modification, alternatives, and variations derived from the scope and the meaning of the scope of the claims and equivalents of the claims should be construed as being included in the scopes of the aspects.

What is claimed is:

1. A display device comprising:
a substrate on which a light emitting area and an auxiliary electrode contact part are defined;
an auxiliary electrode formed on the substrate and connected to a low potential driving power;
a conductive layer formed on the auxiliary electrode in the auxiliary electrode contact part;
an organic layer covering the conductive layer; and
a cathode electrode formed on the organic layer,
wherein the conductive layer is formed of a material having a lower surface tension than that of the organic layer.

2. The display device of claim 1, wherein the organic layer comprises at least one opening which exposes at least one region of the conductive layer, and
wherein the cathode electrode is in direct contact with the conductive layer through the at least one opening.

3. The display device of claim 2, wherein the cathode electrode comprises:
a first cathode electrode formed on a region of the auxiliary electrode where the at least one opening is not formed; and
a second cathode electrode covering the first cathode electrode and in direct contact with the conductive layer through the at least one opening.

4. The display device of claim 3, wherein the first cathode electrode and the second cathode electrode include magnesium, and
wherein a content of the magnesium of the second cathode electrode is less than a content of the magnesium of the first cathode electrode.

5. The display device of claim 1, wherein the conductive layer includes one of Nafion, PCPDT-2T and polyaniline (PANT).

6. The display device of claim 5, wherein an uppermost layer of the auxiliary electrode includes indium tin oxide (ITO).

7. The display device of claim 1, wherein the organic layer includes at least one of an electron transport layer and an electron injection layer.

8. The display device of claim 1, further comprising a bank layer which is formed on the auxiliary electrode and exposes a region of the auxiliary electrode in the auxiliary electrode contact part.

9. The display device of claim 8, wherein at least a portion of a surface of the bank layer has hydrophobicity.

10. The display device of claim 9, wherein a surface of a central region of the conductive layer is lower than a surface of an edge region of the conductive layer.

11. A display device comprising:
a substrate where a light emitting area and an auxiliary electrode contact part are defined;
an auxiliary electrode disposed on the substrate and connected to a low potential driving power;
a conductive layer disposed on the auxiliary electrode in the auxiliary electrode contact part;
an organic layer having an opening and covering the conductive layer; and
a cathode electrode disposed on the organic layer,
wherein the auxiliary electrode and the cathode electrode are connected to each other through the conductive layer in the auxiliary electrode contact part, and
wherein the conductive layer has a surface tension lower than the organic layer.

12. A manufacturing method of the display device, the manufacturing method comprising:
forming, on a substrate on which a light emitting area and an auxiliary electrode contact part are defined, an auxiliary electrode which is formed on the substrate and is connected to a low potential driving power;
forming, in the auxiliary electrode contact part, a conductive layer on the auxiliary electrode;
forming an organic layer which covers the conductive layer;
forming a first cathode electrode on the organic layer; and
performing a reflow process by irradiating a laser to the auxiliary electrode contact part,
wherein, during the reflow process, at least a portion of the organic layer is melted to expose at least one region of the conductive layer.

13. The manufacturing method of claim 12, wherein the conductive layer is formed of a material having a lower surface tension than that of the organic layer.

14. The manufacturing method of claim 13, wherein, during the reflow process, at least a portion of the organic layer is melted and flows due to a difference in surface tension from the conductive layer.

15. The manufacturing method of claim 14, wherein at least one opening which exposes at least one region of the auxiliary electrode is formed in the organic layer and the first cathode electrode by the flowing of the melted organic layer.

16. The manufacturing method of claim 15, further comprising forming a second cathode electrode on the first cathode electrode.

17. The manufacturing method of claim 16, wherein the second cathode electrode is in direct contact with the conductive layer through the at least one opening.

18. The manufacturing method of claim 12, wherein the conductive layer is formed of one of Nafion, PCPDT-2T, and polyaniline (PANT).

19. The manufacturing method of claim 12, further comprising, after the forming the auxiliary electrode, forming, on the auxiliary electrode, a bank layer which exposes a region of the auxiliary electrode in the auxiliary electrode contact part, wherein a portion of a surface of the bank layer has at least hydrophobicity.

20. The manufacturing method of claim 18, wherein the forming the conductive layer comprises:
applying a solution for forming the conductive layer on the exposed region of the auxiliary electrode; and
drying the applied solution.
